(19) United States
(12) Patent Application Publication
(10) Pub. No.: US 2003/0089252 A1
(43) Pub. Date: May 15, 2003

(54) Production of Electroluminescent Devices

(76) Inventor: Greg J. Sarnecki, Ann Arbor, MI (US)

Correspondence Address: HARNESS, DICKEY & PIERCE, P.L.C., P.O. BOX 828, BLOOMFIELD HILLS, MI, 48303, US

(21) Appl. No.: 10/036,350

(22) Filed: Nov. 9, 2001

(51) Int. Cl. B41M 1/10

(52) U.S. Cl. 101/170

(57) ABSTRACT

The invention provides a method of producing an organic light emitting device having a high resolution image of electroluminescent material in which an ink containing the electroluminescent material is applied by a gravure printing process.

### FIELD OF THE INVENTION

The present invention relates to preparing light emitting devices such as for signs and other displays.

### BACKGROUND OF THE INVENTION

Organic light emitting polymers (OLEPs) emit a particular color of visible light (wavelength in the region of 400 to 700 nm) when excited by an electric current. The OLEPs are semiconductive conjugated polymers, such as poly(phenylenevinylene) and its derivatives. The OLEP is applied to a substrate having a layer of material that acts as one electrode, and a second electrode is applied to the other side of the OLEP to provide an organic light emitting device (OLED). The OLEP emits light when an electrical field is applied between the electrodes, causing charge carriers of opposite charge to be injected into the OLEP. At least one of the electrodes is transparent in order to display the emitted light.

To date, most of the work with OLEDs has been with solid displays of one color in which a uniform layer of the OLEP is laid down by one of various coating methods. U.S. Pat. No. 5,247,190, for example, describes applying organic electroluminescent polymers by wet-film coating techniques such as spin coating.

Organic light emitting displays have also been printed by the screen printing methods commonly used for printing electronic circuitry, as described for example by Dino A. Pardo et al., Adv. Mater., vol. 12, No. 17, page 1249 (Sep. 1, 2000). This reference also points out the impracticality of using traditional coating methods such as spin casting or vapor deposition in preparing a pixellated display. A pixellated display is important because OLEDs may display full color images with a pixellated array of red, green, and blue dots. The screen printing process of the reference has reasonably fine registry (needed for a sharply-defined image), but is relatively time-consuming.

The step of applying the transparent electrode material is also time-consuming and expensive. The transparent electrode material, such as indium tin oxide, is generally vapor-deposited or sputtered on the substrate. These processes are expensive, however. Other materials can be used as the transparent electrode material. U.S. Pat. No. 5,976,284 describes photolithographic preparation of a patterned conducting polymer surface as a replacement for an indium tin oxide layer of a display. Conductive coatings based on organic conductive materials, such as the polythiophene mixtures described in Jonas et al., U.S. Pat. No. 5,766,515 can be applied as a transparent electrode for an OLED. J. A. Rogers et al., “Printing, molding, and near-field photolithographic methods for patterning organic lasers, smart pixels and simple circuits,” Synthetic Metals 115 (2000), pages 5-11 describes a soft photolithographic method for patterning organic electronics.

U.S. Pat. No. 5,766,515 describes applying a layer of its electrode material by spraying, application by a doctor blade dipping, roller applicator, gravure “printing,” silk screen printing, or curtain casting. Gravure “printing” of a coating layer is more commonly referred to as gravure coating. In gravure coating, the coating material is applied to the entire length of a gravure roller, and a doctor blade removes excess coating. The web being coated tangentially contacts the gravure roller to accept the coating. The gravure coating method applies a uniform, continuous coating on a surface. Gravure coating and the other methods mentioned by the '515 patent for applying the electrode material could also be used to apply a layer of an OLEP for making a solid display of a single color, but would not be suitable for creating a pixellated array of different electroluminescent materials.

A faster, less expensive method of producing a full-color OLED with higher image resolution is desirable. A less expensive, full-color OLED would allow more widespread use of this promising technology.

### SUMMARY OF THE INVENTION

The invention provides a method of printing a conductive material, especially a semiconductive material such as an OLEP, by gravure printing into an array, especially a pixellated array, on a flexible substrate. Conductive materials that have a conductivity of not more than about 10⁵ ohm⁻¹m⁻¹ are generally considered to be semiconductors.

In a particular embodiment, the invention provides a method of gravure printing an electroluminescent material in a pixellated array on a substrate. The term “pixel” refers to the smallest unit of the printed image. In a single color array, each pixel is a single point or dot of the image of that color. The “dots” need not be round, but they should be small enough and arrayed so as to permit the desired image resolution. In a full color image, each pixel may be one dot or two or more dots of different colors closely located, depending upon the architecture of the pixel. A pixellated array may, for example, have a resolution of at least about 300 lines per inch.

The gravure printing process is explained in detail in the Gravure Association of America's book “Gravure Process and Technology” (1991), among other publications. Gravure printing processes can be generally grouped as rotogravure, reverse gravure, gravure offset, and intaglio process. The substrate may then be a continuous web or separate sheets, leading to the subtypes of web gravure and sheetfed gravure.

Gravure printing offers several advantages over the screen printing, inkjet, and other methods previously used to prepare OLEDs. First, gravure printing can be carried out at much faster printing speeds. Secondly, gravure printing produces an image with excellent definition. Full-color OLEDs can be printed with relatively small pixels. Another key advantage is that gravure printing allows a wide range of carrier solvent, being able to print, for example, aqueous, alcoholic, ester-based, ketonic, aromatic hydrocarbon, and aliphatic hydrocarbon solvent-based inks. Furthermore, gravure inks do not need to be formulated at extremes of viscosity, while screen inks need to be quite viscous and inkjet inks watery thin. Gravure inks are of intermediate viscosity and are, accordingly, easier to formulate and handle. The desired print thickness can be controlled with gravure printing by controlling the depth of the cells. In addition, electrostatic assist allows better transfer in the lower tone range. Hence, fine patterns, if needed, print better with gravure than other printing systems. Standard gravure printing also does not have the dot gain associated with an offset process or some of the uneven densities that can occur with the flexographic printing process. Finally, compared to photolithography, gravure printing is a much faster means of laying down a pattern of material with sufficient definition onto a substrate.

In a further embodiment of the invention, an electroluminescent material is printed by gravure printing onto a conductive electrode. A conductive or semiconductive material is then printed over the electroluminescent material to form a second electrode. The electrode arrays are attached to a printed or wired lead connecting to an electrical source.

### BRIEF DESCRIPTION OF THE DRAWINGS

The present invention will become more fully understood from the detailed description and the accompanying drawings, wherein:

FIGS. 1A-D are schematic diagrams of alternative OLED architectures prepared by the process of the invention; and

FIGS. 2A and 2B are schematic diagrams of alternative OLED matrices prepared by the process of the invention.

### DETAILED DESCRIPTION OF THE PREFERRED EMBODIMENTS

The following description of the preferred embodiment(s) is merely exemplary in nature and is in no way intended to limit the invention, its application, or uses.

At least one organic, semiconductive material is printed in a pixellated array onto a preferably flexible, preferably transparent, substrate by a gravure printing process. The substrate is preferably a plastic film. Among the semiconductive material that can be printed are, without limitation, hole injecting or hole transport materials, electroluminescent materials, electron injecting materials, and electrode materials. The materials may be printed over a coating of a transparent electrode material, such as indium tin oxide, on the flexible, transparent substrate.

In one embodiment, the semiconductive material that is printed is an electroluminescent material. By gravure printing, the electroluminescent material, particularly an OLEP, can be printed in a well-defined graphics image for a display.

Examples of suitable OLEPs include, without limitation, various π-conjugated polymers such as poly(phenylene vinylene) polymers and copolymers, substituted poly(phenylene vinylene) polymers such as poly-(2,5-dialkoxyphenylene vinylene), other poly(arylene vinylene) polymers such as those in which the arylene group is selected from 4,4′-biphenylene, 2,6-naphthylene, 9,10-anthrylene, 2,5-pyridinediyl, and 2,5-thienylene groups, similar polymers in which the vinylene hydrogens are substituted with alkyl groups, aryl groups, and heterocyclic groups of up to 20 carbons or cyano groups, polyfluorenes, polythiophenes, partially conjugated forms of all the above systems, and triple bond (ethynylene) versions of these. Particular examples include, without limitation, those disclosed in Ohnishi, U.S. Pat. No. 5,821,002 (with terminal aryl or heterocyclic groups); poly(tetraphenyl silylene vinylene-co-N-(2-ethylhexyl)carbazole vinylene) [SiPhPVK], described by H. K. Kim et al., 31 Macromolecules 1114-1123 (1998); poly(1,4-phenylene-[1-tetrahydrothiophenioethane-1,2-diyl]) and its derivatives such as poly(1,4-phenylene-[1-methoxyethane-1,2-diyl]).

The OLEP, electroluminescent material, or other organic semiconductor is dispersed or dissolved in a carrier solvent, which can be organic or water-based, to a suitable viscosity for gravure printing. Useful organic solvents include, without limitation, halogenated hydrocarbons, aromatic hydrocarbons, and cyclic ethers, such as chloroform, methylene chloride, dichloroethane, tetrahydrofuran, toluene, and xylene. The solution generally has about 0.05% to about 5.0% by weight of the OLEP or electroluminescent material or other organic semiconductor, preferably about 0.3% to about 3.0% by weight of the OLEP or electroluminescent material or organic semiconductor, and more preferably about 0.5% to about 2.5% by weight of the OLEP or electroluminescent material or organic semiconductor. The concentration can be adjusted to achieve the desired printing viscosity. The printing viscosity can also be adjusted according to the methods described in Towns et al., U.S. Pat. No. 6,153,711, incorporated herein by reference, or by using various additives, including conventional thickeners.

A charge transport material may be included in the OLEP gravure ink in an amount of about 1 to about 40% by weight, preferably from about 2 to about 30% by weight, based on the weight of the OLEP. The electroluminescent gravure ink may contain other materials, including, without limitation, inert binders, charge transport materials, and viscosity adjusters. Inert binders are preferably soluble, transparent polymers such as, without limitation, polycarbonates, polystyrene and copolymers of styrene including SAN, polysulfones, acrylic polymers, and vinyl polymers including vinyl acetate, vinyl alcohol, and vinylcarbazole homopolymers and copolymers.

The gravure ink containing the OLEP or organic semiconducting material may be printed using a rotogravure press. The gravure process uses a cylinder printing member onto which the printing image has been engraved in cells that become filled with the ink. The substrate is printed by passing the substrate between the engraved gravure cylinder and an impression roller that applies pressure. In a typical gravure press arrangement, there is a separate station for each color. After printing with each color, the substrate passes through a heated drying tunnel to dry each printed ink before the next color is printed over it. The printed ink film is dried, for example at a temperature within the range of about 100° F. (37.7° C.) to about 200° F. (93.9° C.) for a time typically within the range of about 0.5 seconds to about 30 seconds. The thickness of the OLEP dots should be between about 10 nm and 1 micron, preferably from about 50 to about 250 nm, after drying.

The substrate onto which the semiconducting material is printed should be flexible enough to be printed in the gravure process. A film of a transparent material can be the substrate. Examples of suitable substrate materials are polyesters such as poly(ethylene terephthalate) and poly(ethylene naphthalate), polycarbonates, acrylic polymers, polysulfones, polyimides, polyalkylenes, particularly polyethylene and polypropylene, vinyl polymers such as poly(vinyl butyrate), polystyrene, and poly (vinyl chloride), ethylene copolymers, including poly (ethylene-vinyl acetate) and poly (ethylene-vinyl alcohol), nylons, polyurethanes, fluorocarbon polymers, polyacrylonitrile, ultrathin glass (30-50 microns thick), and cellulosic polymers such as nitrocellulose.

The substrate upon which the electroluminescent materials are printed is preferably translucent, more preferably transparent to the light emitted when the electroluminescent materials are activated. It is also possible to carry out the gravure printing on an opaque substrate and to apply a transparent layer over the gravure printing to protect the printed image. The process will be described with reference to printing on a transparent substrate; it should be understood that the display device could be made by applying a transparent film over a printed opaque substrate.

The substrate could also be rigid, such as a rigid glass substrate, when the semiconductive material is printed by offset gravure printing.

The electrical device of prepared by the method of the invention may have a cathode, an anode, and a gravure-printed semiconductive material between the cathode and the anode. In a preferred embodiment, the semiconducting material is an electroluminescent material, as described above. The electroluminescent materials may be printed over a coating of a transparent hole-injecting electrode material on the flexible, transparent substrate. Examples of suitable transparent electrode materials include indium tin oxide, indium zirconium oxide, and fluorine tin oxide. A low work-function metal, such as calcium, aluminum, gold, and silver, is typically used as the electron-injecting electrode. The metal may be vacuum deposited in a thin layer, for example about 10 nm.

The electrical device including the electroluminescent material may have one or more additional layers of semiconductive materials, each of which may also be printed in a pixellated array by a gravure printing process.

Charge transport materials can be used to increase the electroluminescent intensity and reduce the inception voltages. The material used for the hole transporting layer should be matched with the electroluminescent material used. For example, PPV may be a hole transporting material when the OLEP is MEH-PPV. Suitable hole transport layer materials include, without limitation, poly(phenylenevinylene) and its derivatives, polypyrrole, polyaniline, pyrazoline derivatives, arylamine derivatives, stilbene derivatives, diamines such as triphenyidiamine derivatives, polythiophene and its derivatives, such as the polythiophene mixture of U.S. Pat. No. 5,766,515, poly(N-vinylcarbazole), and other semiconducting conjugated polymers, such as those described in U.S. Pat. Nos. 5,247,190 and 4,539,507, incorporated herein in their entirety by reference, as well as combinations of these. These conjugated polymers are made conductive by doping, for example PEDOT/PSS (polyethylene 3,4-dioxythiophene doped with polystyrene sulfonate).

The hole injecting layer and/or the hole transporting layer may also be printed by gravure printing processes. Gravure printing is desirable because of the ability to print these layers in a precise, limited area. A solution or dispersion of an organic hole-injecting material can be printed in a pixellated array, and one or more semiconductive materials, such as OLEPs, can be printed over the hole-injecting material so that a pixel of the hole-injecting material underlies each pixel of the semiconductive material. A thin layer of an electron-injecting material can then be deposited over each pixel of the printed image. The charge transport material should be applied at a dry thickness of from about 1 nm to about 1 micron, preferably from about 2 nm to about 500 nm, more preferably from about 5 nm to about 200 nm.

The transparent hole-injecting electrode may alternatively be printed or coated with glycerol, as disclosed by H. Kim and Z. H. Kafafi et al., “Surface Emitting Organic Electroluminescent Devices Using High Work function Electrode Contacts,” Proc. of SPIE, Vol. 4464 (San Diego, 2001), or metallized with a layer of metal thin enough to preserve the transparency of the electrode, for example 0.5 nm platinum. The electrode may also be oxygen plasma treated.

A layer of an electron transport material and/or a layer of an electron injecting material such as LiF may be used in between the OLEP and the electron injecting electrode. Electron transport materials include, without limitation, oxadiazole derivatives, anthraquinodimethane and its derivatives, benzoquinone and its derivatives, naphthaquinone and its derivatives, anthraquinone and its derivatives, tetracyanoanthraquinodimethane and its derivatives, fluorenone derivatives, diphenyldicyanoethylene and its derivatives, diphenoquinone derivatives, metal complexes of 8-hydroquinoline and its derivatives, poly(phenylene quinolene), and combinations of these. These layers may likewise be printed by a gravure printing process in the precise locations needed for the pixellated array of electroluminescent materials.

When a layer of hole-injecting material covers the substrate, both an image of the semiconducting material and a reverse image of an insulating material may be applied. The electron-injecting material may then be applied over not only the semiconducting material but also over part or all of the non-image area without contacting the hole-injecting material (i.e., without shorting out the display device).

A second electrode is applied as the last material. The second electrode may be a metal such as aluminum, gold, silver, copper, or alloys or oxides of these applied by vapor deposition, sputtering, or other techniques. The cathode may advantageously be a low work function cathode such as calcium or magnesium. The cathode may be further optimized by judicious use of a thin passivating layer such as LiF that protects the cathode from destructive breakdown.

Opaque substrates can be used with “top-emitting” devices, in which the cathode material is transparent, such as very thin layers of metals (e.g. less than 1 nm).

The OLED may include a filter layer to convert a color of light emitted from the electroluminescent material to a different color of light. Materials useful for such filters include transparent or semi-transparent inks printed on the other side of the transparent substrate through which the light is emitted. The transparent ink may be gravure coated or, preferably, may be gravure printed over desired pixels of the electroluminescent array.

When an electric field is applied, the electrodes inject oppositely charged charge carriers (i.e., holes and electrons) into the polymer layer. The charge carriers recombine and decay radiatively, causing the OLEP to emit light. An OLEP precursor material may be printed on the first substrate instead, and the OLEP may be formed from the precursor directly on the substrate. If an OLEP precursor is applied, the precursor is then converted to the OLEP by application of heat, UV radiation, electron beam radiation, or other means.

In an embodiment of the gravure printing method, two or more different electroluminescent materials are printed in a closely registered pixellated array. “Closely registered” pixels may be formed from a plurality of different colored dots that are slightly offset from each other. A full-color electroluminescent display can be prepared by gravure printing, on a transparent substrate flexible enough for gravure printing, registered, pixellated arrays of each of three different electroluminescent materials with alternating layers of transparent electrodes. The pixels can contain electroluminescent materials that emit light at red, blue, and green wavelengths to provide a full-color image.

In one arrangement of the device, three pixels are closely positioned, one blue, one green printed over with blue, one red overprinted with blue. The blue acts as a hole transporting layer when layered with the OLEPS of other colors, with the color produced being that of the material emitting the longest wavelength.

As an alternative arrangement of the device, a second, photoluminescent material may be coated in a layer or printed in a pattern on the substrate. The second, photoluminescent material will convert the color of light emitted from the gravure-printed first electroluminescent material to another color of light. For example, a material emitting blue light will have this light absorbed by a second material with a smaller bandgap; re-emission of this light will occur at the bandgap energy and thus the light will have been converted from blue to, e.g., red. Thompson et al., U.S. Pat. No. 6,013,982, which is incorporated herein by reference, describes such materials.

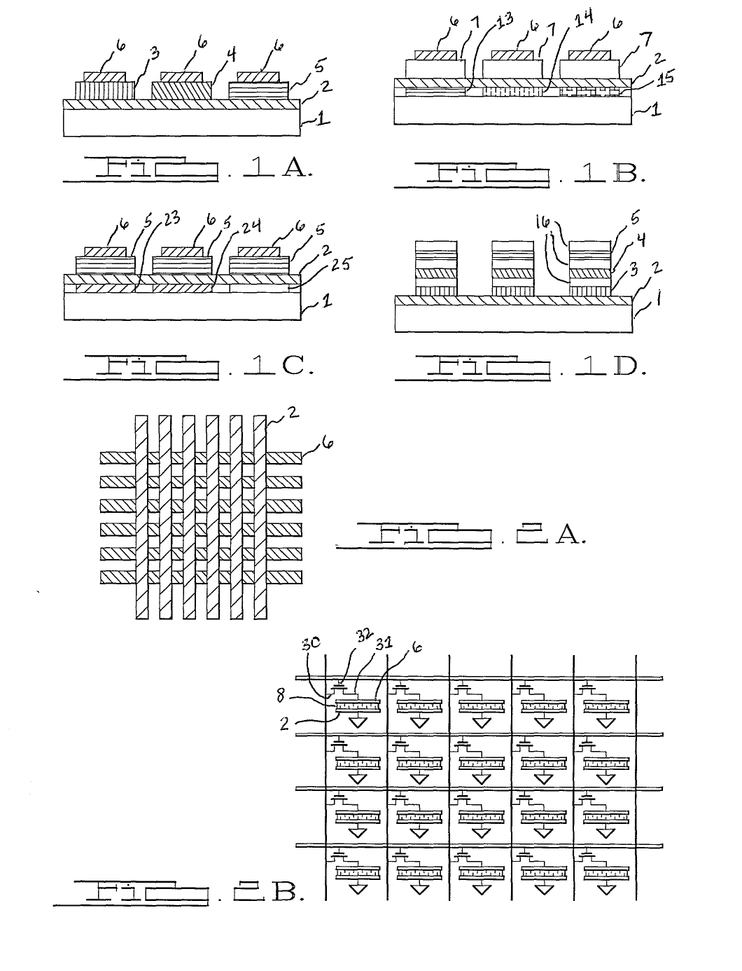

The pixels may have various architectures, as shown in FIGS. 1A-D. In the arrangement of FIG. 1A, a transparent substrate 1 has thereon an anode 2 (e.g., a polyethylene terephthalate film with a layer or line of indium tin oxide). Dots of red-, green-, and blue-light emitting OLEPs (3, 4, and 5, respectively) are printed in a closely registered array onto the electrode. An array of lines or dots 6 of a cathode material is printed on top of each OLEP dot. In another arrangement shown in FIG. 1B, cyan, magenta, and yellow filter dots (13, 14, and 15) are printed in a closely registered array between the transparent substrate 1 and the electrode 2. Layered dots 7 of a white-light emitting OLED and cathode 6 are printed above each filter dot. In FIG. 1C, the white light OLED dots of FIG. 1B are replace by blue light OLEP dots 5, and the filters are replaced by color changing media dots 23 and 24, which absorb the blue light emitted from blue light OLEP dots 5 to re-emit the energy as red and green light, respectively. Dot 25 represents a material that passes the blue light without alteration. FIG. 1D represents stacked layers of red, green, and blue OLEP dots, each with its own transparent addressable cathode 16. Each stack emits red, blue, green, a color from a combination of two emitted lights, or white light depending upon which of the cathodes are addressed. Such structures are known for example from Forrest et al., U.S. patent application 726482, filed Dec. 1, 2000, incorporated herein by reference.

The semiconducting device may be printed in either passive or active matrix addressing arrangements. In passive matrix addressing illustrated in FIG. 2A, the cathodes 6 are applied in horizontal lines and the anodes 2 in vertical lines. Each line is independently addressable to be on or off. The semiconductor material is printed by gravure printing between the cathode and anode lines at each point where the lines cross. The anode and cathode lines can also be printed by gravure printing. In active matrix addressing, shown in simplified form in FIG. 2B, each device with cathode 6, OLEP and any associated layers represented by layer 8, and anode 2 is connected to a thin film transistor switch including a source 30, drain 31, and gate 32. The transparent electrode may then be a continuous layer over the whole substrate.

In a still further embodiment, the OLED is coated, for example by gravure coating, by an oxygen- and water-impermeable layer such as a layer of poly(vinylidene chloride). The OLED may also be metallized with a thin layer of metal or laminated by extrusion or adhesion lamination with a metallized film such as metallized poly(ethylene terephthalate). The substrate may be a PVDC-coated or metallized substrate, for example PDVC-coated or metallized poly(ethylene terephthalate), to provide resistance to water and oxygen on both sides of the OLED.

The OLED manufacturing process may also employ a lamination step. Gravure printing has been used with lamination steps in printing packaging materials, and the process for preparing a laminated OLED is essentially the same. In lamination applications, a printed film material is laminated to another film using an adhesive selected from various solvent-based, solventless, and water-based adhesives. A laminate can also be prepared using an extrusion process where the printed side of a first web is brought in contact a second web in a combining nip between opposing rolls. The extruder applies a layer of molten polymer, usually polyethylene heated to between 550-625° F., in to the nip between the first and second web. The rolls apply pressure to laminate the two webs to one another. In preparing the OLED, the printed semiconductive material or materials will be printed on the inside surface of one of the laminated films or on the inside surfaces of each of the laminated films. A thin sheet of foil, for example to act as an electrode material can also be applied by lamination to a film printed with the semiconductive material.

Any conventional lamination process may be used, for example wet bonding, dry bonding, hot melt or wax laminating, extrusion lamination, and thermal or heat laminating techniques. Dry bonding involves applying adhesive to one of the films or webs. The solvent is evaporated from the adhesive and the adhesive-coated web is combined with the other web material by heat and pressure or by pressure only. A variety of adhesives may be used for this purpose, including single part and two-part (e.g., epoxy-amine) solvent-borne adhesives, waterborne adhesives, and solventless adhesives. Curable adhesives include, besides the two-part adhesives, moisture curing or radiation-curing adhesives. The inks of the invention offer the advantage of low retention of the solvents that would interfere with the crosslinking reaction of solventless adhesives and affect adhesive strength.

The invention is further described in the following examples. The examples are merely illustrative and do not in any way limit the scope of the invention as described and claimed. All parts are by weight unless otherwise indicated.

### EXAMPLE 1

### Printing a Single Color Array Image

Poly-(2-methoxy-5-(2′-ethylhexyloxy)-1,4-phenylenevinylene) (MEH-PPV) was prepared by polymerizing 1,4-bis(chloromethyl)-2-methoxy-5-(2′-ethylhexyloxy)-benzene with excess potassium tert-butoxide in tetrahydrofuran, followed by precipitation of the product in methanol. The polymer precipitated was collected by vacuum filtration, washed with further portions of methanol, and vacuum dried. The dried MEH-PPV, 0.79 parts by weight, was then dissolved in 100 parts by weight of a mixture of toluene and acetone (2:1 by volume).

The polymer solution was pipetted onto a flat image plate above the image area of a draw down gravure press. The printing plate was a 75 linescreen with vignettes of 100%, 75%, 50%, and 25% coverage. The polymer solution was printed onto a sheet of polyethylene terephthalate coated with indium tin oxide with the gravure press. Examination of the dot structure with a microscope under fluorescent light revealed well-defined dots in an arrayed pattern.

### EXAMPLE 2

### Printing a Multi-Color Array Image

A purified solution of the sulfonium salt of poly(1,4-phenylene[1-tetrahydrothiophenioethane-1,2-diyl]) in methanol and water is printed onto a sheet of polyethylene terephthalate coated with indium tin oxide with the gravure press of Example 1. The printing plate has an array of 75, 150, and 300 linescreens in across the plate in one direction and 10%, 20%, 30%, 40%, 70%, and 100% coverages across the plate in the direction perpendicular to the linescreens.

The print of the sulfonium salt of poly(1,4-phenylene-[1-tetrahydrothiophenioethane-1,2-diyl]) is allowed to fully dry. The printed precursor polymer is then converted thermally, with vacuum, to poly(1,4-phenylene vinylene). A solution of MEH-PPV is prepared according to Example 1 and then printed over the PPV image, using the same gravure press and printing plate, but with a slight offset to ensure that none of the dots overlap. Examination of the dot structure with a microscope under fluorescent light reveals well-defined dots in a pair of arrayed patterns, with one pattern offset slightly from the other.

The invention has been described in detail with reference to preferred embodiments thereof. It should be understood, however, that variations and modifications can be made within the spirit and scope of the invention.

What is claimed is:

1. A method of printing an electrical device, comprising a step of printing in a pixellated array onto a substrate at least one organic semiconductive material by a gravure printing process.

2. A method according to claim 1, wherein the array is a part of a passive matrix array.

3. A method according to claim 1, wherein the array is a part of an active matrix array.

4. A method according to claim 1, wherein at least two electroluminescent materials are printed in a closely registered pixellated array.

5. A method according to claim 1, wherein the substrate is transparent and at least semi-flexible.

6. A method according to claim 5, wherein the substrate comprises a material selected from the group consisting of poly(ethylene terephthalate), poly(ethylene naphthalate), polycarbonates, acrylic polymers, polysulfones, polyimides, polyethylene, polypropylene, vinyl polymers, poly(vinyl butyrate), polystyrene, poly(vinyl chloride), copolymers of ethylene, nylons, polyurethanes, polyacrylonitrile, cellulosic polymers, nitrocellulose, and combinations thereof.

7. A method according to claim 5, wherein the substrate comprises ultrathin glass.

8. A method according to claim 1, wherein the semiconductive material is an electroluminescent material.

9. A method according to claim 8, wherein a second organic semiconductive material is printed by a gravure printing process in a pixellated array overlaying the pixellated array of the electroluminescent material.

10. A method according to claim 8, comprising a step of printing a second organic semiconductive material by a gravure printing process in a pixellated array, wherein the electroluminescent material is printed over the pixels of the second organic semiconductive material.

11 A method according to claim 8, wherein the device includes a filter layer capable of converting a color of light emitted from the electroluminescent material to another color of light.

12. A method according to claim 8, wherein the device includes a layer of a photoluminescent material capable of converting a color of light emitted from the printed electroluminescent material to another color of light.

13. A method according to claim 8, in which at least one electrode material is applied by gravure printing.

14. A method according to claim 8, wherein the pixellated array has a resolution of at least about 300 lines per inch.

15. A device produced according to the method of claim 8.

16. A method according to claim 1, further comprising a step of laminating the printed substrate to a film.

17. A method for producing a full-color, electroluminescent display, comprising:
printing on an at least semi-flexible, transparent substrate by a gravure printing process a registered pixellated array of at least three different electroluminescent materials with alternating layers of transparent electrodes.

18. A method for producing an electroluminescent display, comprising the steps of:
printing on an at least semi-flexible substrate by a gravure printing process a closely registered pixellated array of at least three different electroluminescent materials.

19. A method according to claim 18, wherein the combination of the electroluminescent materials provides the ability to display a desired multicolored image.

20. A method of producing a display device, comprising printing at least one semiconductive material by offset gravure printing onto a substrate in a pixellated array.

21. A method according to claim 20, wherein the substrate is a glass substrate.

22. A method according to claim 20, further comprising a step of laminating the printed substrate with a film or foil, wherein the printed semiconductive material is on the inside of the laminate formed.

23. A method of printing a display, comprising the steps of:
(a) coating on an at least semi-flexible substrate a layer of an organic hole injecting material;
(b) gravure printing on the coating an image in a closely registered pixellated array of at least three different electroluminescent materials;
(c) depositing a layer of electron-injecting material over each pixel.

24. A method according to claim 23, wherein the coating step is carried out by gravure coating.

25. A method according to claim 23, including a further step of gravure printing a reverse image of an insulating material between steps (a) and (c) whereby the printed image and reverse image prevent contact between the hole injecting material and the electron injecting material.
